(19) United States
(12) Patent Application Publication
(10) Pub. No.: US 2019/0373708 A1
(43) Pub. Date: Dec. 5, 2019

(54) SMART LIGHT SOURCE

(71) Applicant: National Tsing Hua University, Hsinchu (TW)

(72) Inventors: CHENG-CHIEH LO, Changhua County (TW); JWO-HUEI JOU, Hsinchu City (TW)

(21) Appl. No.: 16/149,158

(22) Filed: Oct. 2, 2018

(30) Foreign Application Priority Data
May 30, 2018 (TW) 107118497

(51) Int. Cl. H05B 37/02; H05B 33/08; H01L 27/32; H01L 33/50

(52) U.S. Cl. CPC H05B 37/0281; H05B 33/0857; H05B 33/0896; H05B 37/0218; H01L 33/504; H01L 33/507; H01L 33/505; H01L 27/322

(57) ABSTRACT

Disclosures of the present invention describe a smart light source consisting of an illumination module, a driver module, and a controller module. The illumination module are particularly designed to have a plurality of first lighting elements and at least one second lighting element, wherein one or more color temperature (CT) reducing films are disposed on a light emission surface of each of the first lighting elements. The first lights radiated from different first lighting elements are converted to a light resemblance with respect to sunlight in morning sessions, a light resemblance with respect to sunlight in early morning sessions or early evening sessions, an orange-white light, or an orange-red light by the CT reducing films. Moreover, the second lighting element is configured to emit a light resemblance with respect to sunlight in noon sessions or a light resemblance with respect to blue sky sunlight.

### BACKGROUND OF THE INVENTION

### 1. Field of the Invention

The present invention relates to the technology field of lighting devices, and more particularly to a smart light source capable of automatically providing an illumination contributed by lights resemblance with respect to sunlight (daylight) in at least one session of local real time which is selected by an user through an controller module.

### 2. Description of the Prior Art

With the development of science technologies, artificial light source is developed from the incandescent bulb invented by Thomas Alva Edison to fluorescent lamp. Furthermore, solid-state lighting devices are recent newly-created artificial light sources, including light-emitting diode (LED), organic light-emitting diode (OLED) and polymer light-emitting diode (PLED).

FIG. 1 illustrates a data plot of color temperature versus power efficiency, and FIG. 2 shows a CIE chromaticity diagram. It is worth noting that, FIG. 2 particularly depicts a Planckian locus (also called blackbody radiation curve) presenting a color temperature variation resemblance with respect to that of sunlight (daylight). According to FIG. 1 and FIG. 2, corresponding light classifications for sunlight (daylight) and lights emitted by various illuminous devices are integrated in following Table (1).

TABLE 1

| Color | Lights emitted by | |
|---|---|---|
| temperature (K) | various illuminous | Sunlight (daylight) |
| <2,500 | Orange-white light | Sunlight in early morning |
| | | sessions or early evening |
| | | sessions has a color |
| | | temperature of 2,000-3,000 |
| | | K. |
| 2,500-5,500 | Warm-white light | Sunlight in morning |
| | | sessions has a color |
| | | temperature of about 4,000 |
| | | K. |
| 5,500-6,500 | Pure-white light | Sunlight in noon |
| | | sessions has a color |
| | | temperature of 5,000-6,000 |
| | | K. |
| >6500 | Cold-white light | Blue sky sunlight has a |
| | | color temperature |
| | | greater than 6,500 K. |

Long-term research reports made by George C. Brainard (PhD. and director of light research program of Thomas Jefferson University in Philadelphia) and NASA have documented how various visible and nonvisible light sources influence both hormonal balance and behavior. Moreover, their current studies further include elucidating the action spectrum of melatonin regulation, investigating the phase shifting capacities of light, studying the influence of light on tumor progression, and testing new light treatment devices for winter depression. For example, the steroid hormone cortisol is known serving a variety of important functions in the human body. In humans, cortisol levels decrease across the habitual waking day and are lowest near habitual bedtime after which time they increase across the habitual night and peak near habitual wake time, regardless of continuous wakefulness or sleep. Moreover, influence of exposure to bright light on cortisol levels has been proved. On the other hand, the pineal gland hormone melatonin is released during the biological night and provides the body's internal biological signal of darkness. Exposure to light both resets the circadian rhythm of melatonin and acutely inhibits melatonin synthesis. It is well known that sunlight is a gift from God. As the sun rises, illumination provided by the sunlight make people feel be spiritful and get activity. On the contrary, people gradually get mental relaxation and let their mind rest during the session of sunset. However, for the specific workers staying in an environment unable to normally receive sunlight illumination, such as spaceman, miner and underground worker, it is difficult or impossible for them to receive potent stimulus induced by sunlight illumination so as to regulate circadian, hormonal, and behavioral systems thereof. As a result, it is presumed that, after working for a certain time period, these specific workers may suffer from physical disorder which further brings health problems to the workers.

Accordingly, illuminous device manufactures develop and provide a color temperature tunable (CTT) illuminous device for users to decide and adjust the brightness and color temperature of a light emitted from the CTT illuminous device by themselves. FIG. 3 shows a framework view of the CTT illuminous device, mainly comprising an lighting element array constituted by a plurality of first light emitting devices (LEDs) 2′ and a plurality of second LEDs 3′. The first LEDs 2′ are configured to emit warm light 4′ with color temperature in a range from 2,500 K to 4,000 K, and the second LEDs 3′ are set to emit cold light 5′ with color temperature in a range between 6,000 K and 10,000 K. Moreover, FIG. 1 also depicts that the warm light 4′ and the cold light 5′ are further mixed to an output light 6′. Therefore, it is understood that color temperature of the output light 6′ is dependent upon a mixing ratio of the warm light 4′ and the cold light 5′.

Although the CTT illuminous device 1′ is developed for users to decide and adjust the brightness and color temperature of the light emitted from the CTT illuminous device 1′ by themselves, long-term collections of user feedbacks make engineers skilled in development and manufacture of illuminous devices know that, the CCT illuminous device 1′ still exhibits many drawbacks in practical use as follows:
(1) Maximum adjustment range of the color temperature of the CCT illuminous device 1′ relies upon the color temperature adjustable capability of the plurality of first LEDs 2′ and the plurality of second LEDs 3′. In addition, it is hard and must spend expensive cost for the manufacture of the CCT illuminous device 1′ due to the fact that the CCT illuminous device 1′ comprises a larger amount of LEDs for radiating various lights with different color temperature.
(2) Adjustment of the brightness and color temperature of the output light 6′ is achieved by varying corresponding driving voltages or currents for the first LEDs 2′ and the second LEDs 3′. However, it is known that LED's brightness would rise with the increasing of color temperature in a normal case, that causes the CCT illuminous device 1′ fails to be individually adjusted the brightness and the color temperature thereof.

From above descriptions, it is clear and understood that how to design a lighting device or apparatus with luminance and color temperature both tunable function has now became an important issue. Accordingly, the inventors of the present application have made great efforts to make inventive research thereon and eventually provided a smart light source.

### SUMMARY OF THE INVENTION

The primary objective of the present invention is to provide a smart light source, comprising: an illumination module, a driver module, and a controller module. The illumination module comprises a plurality of first lighting elements and at least one second lighting element, wherein one or more color temperature (CT) reducing films are disposed on a light emission surface of each of the plurality of first lighting elements. By such arrangement, first lights radiated from different first lighting elements would be converted to a light resemblance with respect to sunlight in morning sessions, a light resemblance with respect to sunlight in early morning sessions or early evening sessions, an orange-white light, or an orange-red light by the CT reducing films. Moreover, the second lighting element is configured to emit a high CT light, i.e., a light resemblance with respect to sunlight in noon sessions or a light resemblance with respect to blue sky sunlight.

In order to achieve the primary objective of the present invention, the inventor of the present invention provides one embodiment for the smart light source, comprising:

an illumination module, comprising:
a plurality of first lighting elements, wherein each of the plurality of first lighting elements is configured to emit a first light;
at least one second lighting element for emitting a second light; and
one or more color temperature reducing films, being connected a light emission surface of each of the plurality of first lighting elements and stacked to each other, so as to apply a color temperature reducing process to each of the first lights; wherein the first lights have a color temperature rolling off with the adding of the number of the color temperature reducing films;
a driver module, being electrically connected to the illumination module; and
a controller module, being used for controlling the driver module, and comprising:
   a daylight database, storing with a plurality of daylight data corresponding to a plurality of areas, respectively;
   an area selecting unit for choosing a specific area from the daylight database;
   a clock unit for providing a local real time of the specific area chosen by the area selecting unit; and
   a microprocessor, being electrically connected to the area selecting unit, the clock unit and the daylight database, and being configured to generate a controlling signal to the driver module based on the daylight data and the local real time corresponding to the specific area chosen by the area selecting unit, such that the driver module drives at least one of the plurality of first lighting elements and/or the at least one second lighting element to make light emission according to the controlling signal.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1 shows a data plot of color temperature versus power efficiency;

FIG. 2 shows a CIE chromaticity diagram;

FIG. 3 shows a framework view of a color temperature tunable (CTT) illuminous device;

FIG. 4 shows a stereo diagram of a first embodiment of a smart light source according to the present invention;

FIG. 5 shows a framework view of the first embodiment of the smart light source;

FIG. 6 shows a stereo diagram for describing a first lighting element and a color temperature reducing film;

FIG. 7 shows a cross-sectional side view of the color temperature reducing film;

FIG. 8 shows a cross-sectional side view for describing the first lighting element and the color temperature reducing film;

FIG. 9 shows a cross-sectional side view for describing the first lighting element and the color temperature reducing film;

FIG. 10 shows a first CIE chromaticity diagram with measurement data obtained from LED components;

FIG. 11 shows a second CIE chromaticity diagram with measurement data obtained from the LED components;

FIG. 12 shows a third CIE chromaticity diagram with measurement data obtained from OLED components;

FIG. 13 shows a block diagram of a controller module; and

FIG. 14 shows a framework diagram of a second embodiment of the smart light source according to the present invention.

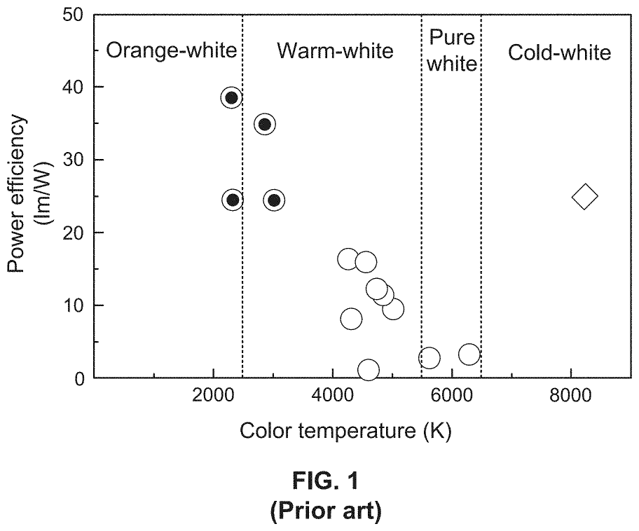

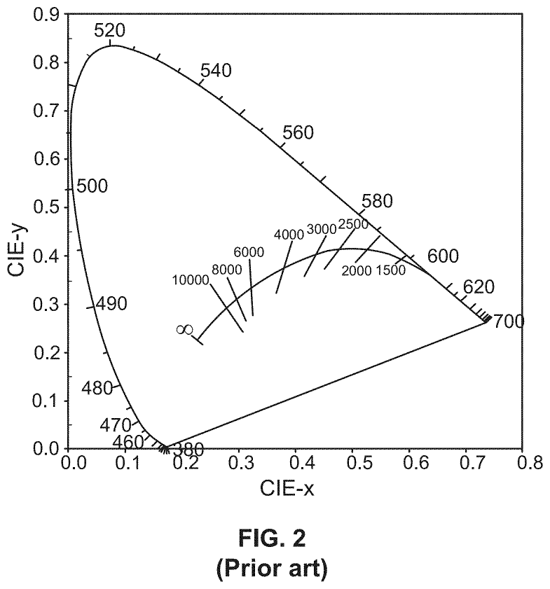

### DETAILED DESCRIPTION OF THE PREFERRED EMBODIMENTS

To more clearly describe a smart light source according to the present invention, embodiments of the present invention will be described in detail with reference to the attached drawings hereinafter.

First Embodiments of the Smart Light Source

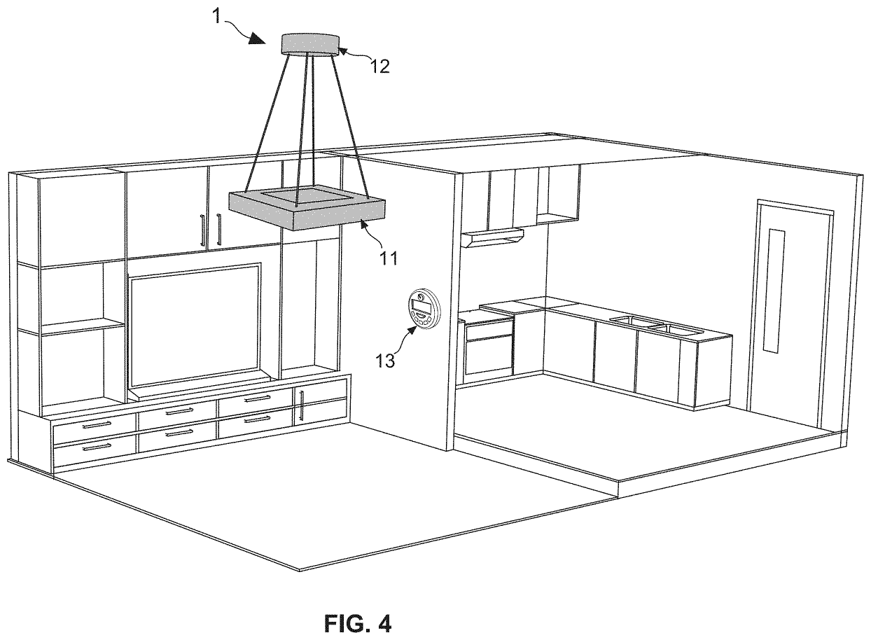

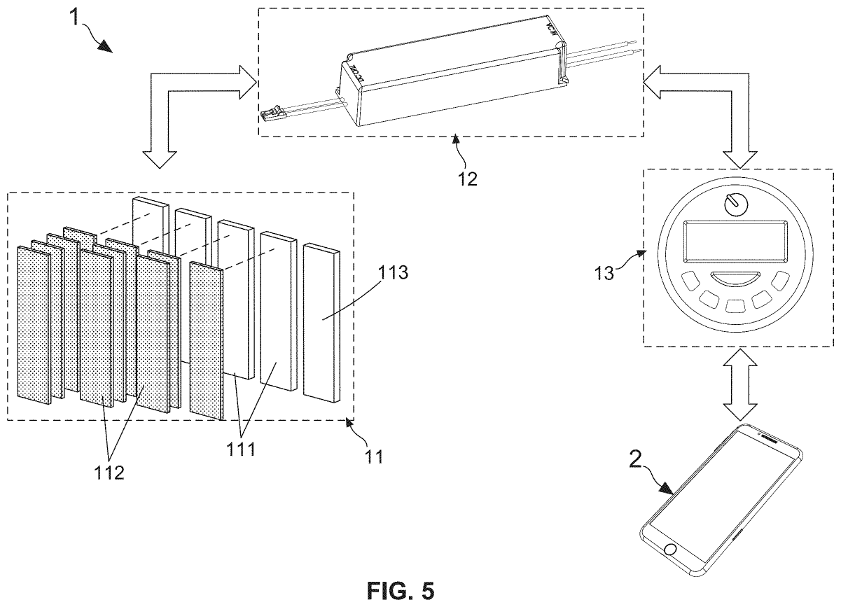

With reference to FIG. 4, there is provided a stereo diagram of a first embodiment of a smart light source according to the present invention. Moreover, FIG. 5 shows a framework view of the first embodiment of the smart light source. As FIG. 4 shows, the smart light source 1 of the present invention is applied in an environment unable to receive a normal illumination provided by daylight (sunlight), such as spaceship, spacecraft, space capsule, or mine Particularly, this smart light source 1 is configured to provide an illumination contributed by lights resemblance with respect to sunlight (daylight) in a specific session of time. It is worth mentioning that, there are many small apartments or houses cannot have an enough sunlight illumination due to the fact that overcrowded apartment buildings have now constructed in modern cites. On the other hand, for the underground workers such as miner or subway employees, it is difficult or impossible for them to receive the illumination of sunlight. Therefore, the smart light source 1 of the present invention can also be applied in the environment like the mine or the underground space.

From FIG. 4 and FIG. 5, it is understood that the smart light source 1 mainly comprises an illumination module 11, a driver module 12 and a controller module 13, wherein the illumination module 11 comprises a plurality of first lighting elements 111, at least one second lighting element 113 and one or more color temperature reducing films 112. According to the basic design of the present invention, both the first lighting element 111 and the second lighting element 113 are selected from the group consisting of fluorescent lighting device, LED component, QD-LED component, OLED component, fluorescent lighting device, LED lighting device, QD-LED lighting device, OLED lighting device, lighting tube, planar lighting device, and light bulb. Preferably, high color temperature lighting elements or devices are more suitable for being as the first lighting elements 111 and the second lighting element 113.

Particularly, the color temperature reducing films 112 are connected a light emission surface of each of the plurality of first lighting elements 111 and stacked to each other, so as to apply a color temperature reducing process to each of first lights radiated from the plurality of first lighting elements 111. It is interesting that both the color temperature and the luminance of the first lights are changed after the color temperature reducing process is completed. It is worth mentioning that, comparing to the first lighting elements 111 connected with only one color temperature reducing film 112, the first lights emitted by the first lighting elements 111 connected with two or more color temperature reducing films 112 present better and obvious effect on color temperature reducing. Experimental data for describing the reduction of the luminance and color temperature of the first lights in response to the stack numbers of the temperature reducing films 112 are integrated in following Table (2).

TABLE 2

| Stack numbers | Color | Luminance | |
|---|---|---|---|
| of the color | temperature | of the | CIE |
| temperature | of the first | first light | coordinates |
| reducing films | light (K) | (1x) | (x, y) |
| 0 | 4920 | 4020 | (0.34, 0.32) |
| 1 | 3575 | 3040 | (0.39, 0.35) |
| 2 | 2788 | 2230 | (0.43, 0.37) |
| 3 | 2403 | 1180 | (0.46, 0.38) |
| 4 | 2138 | 839 | (0.49, 0.38) |
| 5 | 1852 | 634 | (0.52, 0.39) |

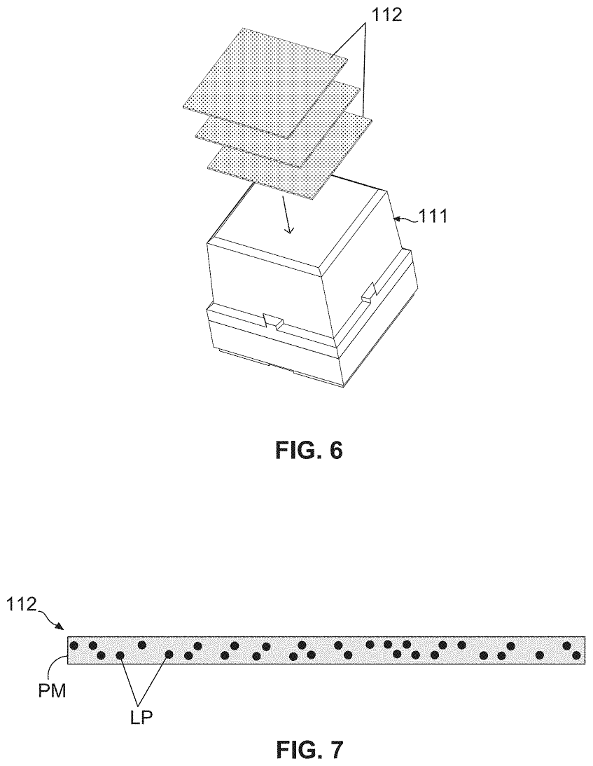

Please continuously refer to FIG. 6, which illustrates a stereo diagram for describing the first lighting element and the color temperature reducing film. Moreover, FIG. 7 shows a cross-sectional side view of the color temperature reducing film According to the particular design of the present invention, there are one or more color temperature reducing films 112 connected to the light emission surface of each one first lighting element 111. Moreover, from the experimental data of Table (2), it is found that the first lights have a color temperature rolling off with the adding of the number of the color temperature reducing films 112. It is worth noting that, the experimental data of Table (2) also indicate that the first lights are eventually converted to an orange-white light or an orange-red light with the color temperature in a range between 1,000K and 2,500K.

In the present invention, the color temperature reducing film 112 is a light conversion film comprising a polymer substrate PM and a plurality of light conversion particles LP, wherein the light conversion particles LP are doped in or enclosed by the polymer substrate PM. Moreover, the manufacturing material of the polymer substrate can be polydimethylsiloxane (PDMS), polystyrene (PS), polyethylene terephthalate (PET), polycarbonate (PC), cycloolefin co-polymer (COC), cyclic block copolymer (CBC), polylactide (PLA), polyimide (PI), or combination of the above-mentioned two or above materials. On the other hand, the light conversion particles LP can be quantum dots, wherein the quantum dot is selected from the group consisting of Group II-VI compounds, Group III-V compounds, Group II-VI compounds having core-shell structure, Group III-V compounds having core-shell structure, Group II-VI compounds having non-spherical alloy structure, and combination of the aforesaid two or above compounds. Exemplary materials of the quantum dots for being used as the light conversion particles LP are integrated and listed in following Table (3). Moreover, relations between the fluorescence color of the excitation light and the QDs sizes are also summarized in following Table (4).

TABLE 3

| | Corresponding exemplary |
|---|---|
| Types of quantum dot (QD) | material |
| Group II-VI compounds | CdSe or CdS |
| Group III-V compounds | (Al, In, Ga)P, (Al, In. Ga)As, |
| | or (Al, In. Ga)N |
| Group III-V compounds having | CdSe/ZnS core-shell QD |
| core-shell structure | |
| Group III-V compounds having | InP/ZnS core-shell QD |
| core-shell structure | |
| Group II-VI compounds having | ZnCdSeS |
| non-spherical alloy structure | |

TABLE 4

| Fluorescence color of the | |
|---|---|
| excitation light | Size of QDs |
| Blue-green | 2-7 nm |
| Green | 3-10 nm |
| Yellow | 4-12 nm |
| Orange | 4-14 nm |
| Red | 5-20 nm |

In addition, the light conversion particles LP can also be particles of a phosphor, and the phosphor can an aluminate phosphor, a silicate phosphor, a phosphate phosphor, a sulfide phosphor, or a nitride phosphor. Exemplary materials of the phosphor for being used as the light conversion particles LP are integrated and listed in following Table (5).

TABLE 5

| Types of fluorescent powder | Corresponding exemplary material |
|---|---|
| Aluminate phosphor | Eu doped Y—Al—O multi-composition |
| | phosphor |
| Silicate phosphor | Ca₃Si₂O₇:Eu²⁺ |
| Phosphate phosphor | KSr₁₋ₓPO₄:Tbₓ |
| | K₂SiF₆:Mn⁴⁺ (KSF) |
| Sulfide phosphor | ZnS:X |
| | X = Au, Ag, Cu, Mn, Cd |
| Nitride phosphor | β-SiAlON:Eu²⁺ |
| Other-type phosphor | SrGa₂S₄:Eu²⁺ (SGS) |

Table (3) and Table (5) are not used for limiting the formation or manufacturing material of the color temperature reducing film 112. For example, the color temperature reducing film 112 can also be constituted by a polymer substrate and at least one light conversion coating layer formed on the polymer substrate. In addition, when the color temperature reducing film 112 is constituted by the polymer substrate PM and a plurality of QDs (i.e., light conversion particles LP), it is able to further formed an oxygen and moisture barrier on the color temperature reducing film 112. The oxygen and moisture barrier is made of a specific material selected from the group consisting of polyethylene terephthalate (PET), polyethylene naphthalate (PEN), poly(methyl methacrylate) (PMMA), silica, titanium oxide, aluminum oxide, and combination of the aforesaid two or above materials.

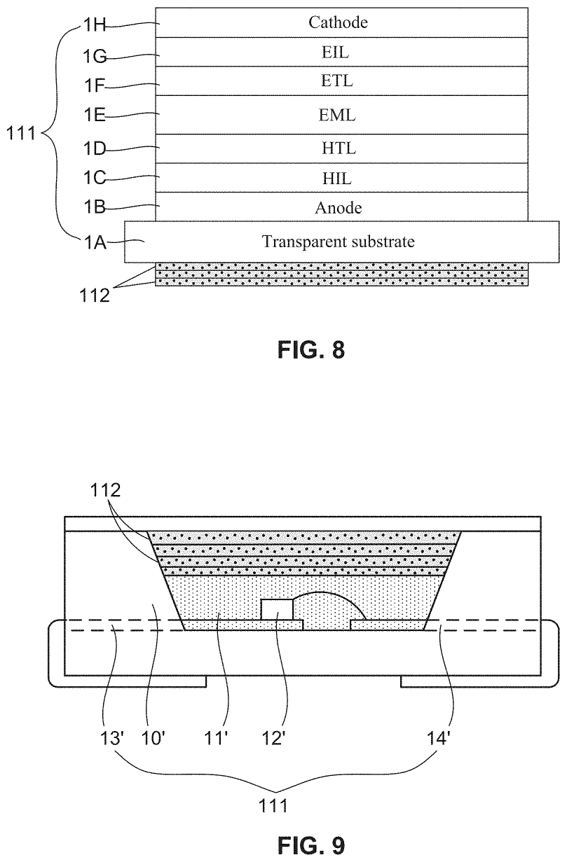

FIG. 8 illustrates a cross-sectional side view for describing the first lighting element and the color temperature reducing film From FIG. 4, it is understood that an OLED component is adopted for being the first lighting element 111, which comprises: a transparent substrate 1A, an anode 1B formed on one surface of the transparent substrate 1A, a hole injection layer (HIL) 1C formed on the anode 1B, a hole transport layer (HTL) 1D formed on the HIL 1C, an emission layer (EML) 1E formed on the HTL 1D, an electron transport layer (ETL) IF formed on the EML 1E, an electron injection layer (EIL) 1G formed on the ETL IF, and a cathode 1H formed on the EIL 1G. FIG. 8 also depicts that a plurality of color temperature reducing films 112 are disposed on an emission surface of the OLED component (i.e., the other surface of the transparent substrate 1A), wherein the plurality of color temperature reducing films 112 are stacked to each other.

On the other hand, FIG. 9 shows a cross-sectional side view for describing the first lighting element and the color temperature reducing film. From FIG. 9, it is understood that an LED component is adopted for being as the first lighting element 111, which comprises: an insulation body 10′, an LED die 12′, and encapsulation member 11′, wherein the insulation body 10′ has an accommodating recess for receiving the LED die 12′. Moreover, both a first electrical member 13′ and a second electrical member 14′ have a welding portion and electrical connection portion. The two welding portions locate in the accommodating recess, but the electrical connection portions extend out of the insulation body 10′. Because there are particles of a phosphor doped in the encapsulation member 11′, a short-wavelength light emitted by the LED die 12′ would be converted to a white light, and then the white light would be converted to an orange-white light or an orange-red light having color temperature of 1,000-2,500K by the color temperature films 112.

An LED component capable of emitting a pure-white light with color temperature of 6,000K is used as the first lighting elements 111 and the second lighting element 113 in experiment I. In experiment I, the smart light source 1 comprises four first lighting elements 111 and one second lighting element 113. It needs further explain that, No. 1 of the four first lighting elements 111 is connected with one color temperature reducing film 112, and No. 2, No. 3 and No. 4 of the four first lighting elements 111 are connected with the color temperature reducing films 112 with stacked numbers of two, three and four, respectively. Moreover, in experiment I, the color temperature reducing film 112 comprises a polymer substrate PM and a plurality of QDs (i.e., light conversion particles LP), wherein the QDs are spread in the polymer substrate PM and having a particle size in a range from 5 nm to 20 nm.

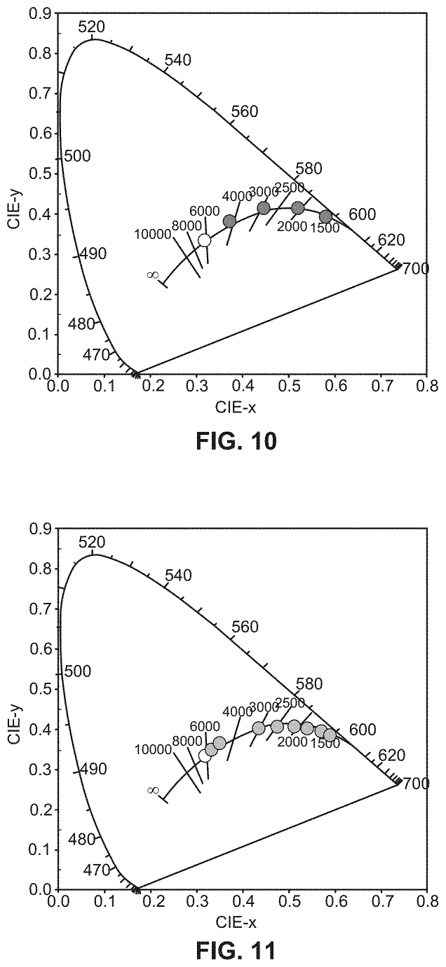

FIG. 10 shows a first CIE chromaticity diagram with measurement data obtained from an LED component. From the experimental data of FIG. 10, it is found that, the first light emitted by the LED components (i.e., the first lighting element 111) connected with one color temperature reducing film 112 has a color temperature of 4,150K so as to be classified to a warm-white light. On the other hand, the first light emitted by the first lighting element 111 connected with two stacked color temperature reducing films 112 has a color temperature of about 3,000K so as to be classified to a warm-white light. Furthermore, both the first light emitted by the first lighting element 111 connected with three stacked color temperature reducing films 112 and the first light emitted by the first lighting element 111 connected with four stacked color temperature reducing films 112 are eventually converted to an orange-white light or an orange-red light with the color temperature in a range between 1,000K and 2,500K. In addition, experimental data of FIG. 10 also indicates that, the first lights have a color temperature rolling off with the adding of the number of the color temperature reducing films 112, and also have a CIE coordinate positioning near a Planckian locus (also called blackbody radiation curve) in the CIE chromaticity diagram.

The LED component capable of emitting a pure-white light with color temperature of 6,000K is also used as the first lighting elements 111 and the second lighting element 113 in experiment II. In experiment II, the smart light source 1 comprises eight first lighting elements 111 and one second lighting element 113. It needs further explain that, No. 1 of the eight first lighting elements 111 is connected with one color temperature reducing film 112, and No. 2 of the eight first lighting elements 111 are connected with two stacked color temperature reducing films 112. Moreover, No. 3, No. 4, No. 5, No. 6, No. 7, and No. 8 of the eight first lighting elements 111 are covered by the color temperature reducing films 112 with stacked numbers of from three to eight, respectively. On the other hand, in experiment II, the color temperature reducing film 112 comprises a polymer substrate PM and a plurality of QDs (i.e., light conversion particles LP), wherein the QDs are spread in the polymer substrate PM and having a particle size in a range from 3 nm to 10 nm.

FIG. 11 shows a second CIE chromaticity diagram with measurement data obtained from the LED components. From the experimental data of FIG. 11, it is found that, the first lights emitted by the first lighting element 111 connected with multi stacked color temperature reducing films 112 have a color temperature rolling off with the adding of the number of the color temperature reducing films. Moreover, CIE coordinates of the eight first lighting elements 111 all position near a Planckian locus (also called blackbody radiation curve) in the CIE chromaticity diagram.

According to the particular design of the present invention, the smart light source 1 are mainly constituted by an illumination module 11, a driver module 12, and a controller module 13, wherein the illumination module 11 are designed to have a plurality of first lighting elements 111 and at least one second lighting element 113, and wherein one or more color temperature (CT) reducing films 112 are disposed on a light emission surface of each of the first lighting elements 111. Obviously, experimental data of FIG. 10 and FIG. 11 have proved that, The first lights radiated from different first lighting elements 111 are converted to a light resemblance with respect to sunlight in morning sessions (˜4,000 K), a light resemblance with respect to sunlight in early morning sessions or early evening sessions (2,000-3,000 K), an orange-white light (1,000-2,500 K), or an orange-red light (1,000-2,500 K) by the CT reducing films 112. Moreover, the second lighting element 113 is configured to emit a light resemblance with respect to sunlight in noon sessions (5,000-6,000 K) or a light resemblance with respect to blue sky sunlight (˜6,500K).

Furthermore, an OLED component capable of emitting a pure-white light with color temperature of 5,400K is used as the first lighting elements 111 and the second lighting element 113 in experiment III. It is known that the light with color temperature of 5,400 K is classified to a pure-white light. In experiment III, the smart light source 1 comprises eight first lighting elements 111 and one second lighting element 113. It needs further explain that, No. 1 of the eight first lighting elements 111 is connected with one color temperature reducing film 112, and No. 2 of the eight first lighting elements 111 are connected with two stacked color temperature reducing films 112. Moreover, No. 3, No. 4, No. 5, No. 6, No. 7, and No. 8 of the eight first lighting elements 111 are covered by the color temperature reducing films 112 with stacked numbers of from three to eight, respectively. On the other hand, in experiment II, the color temperature reducing film 112 comprises a polymer substrate PM and a plurality of QDs (i.e., light conversion particles LP), wherein the QDs are spread in the polymer substrate PM and having a particle size in a range from 5 nm to 20 nm.

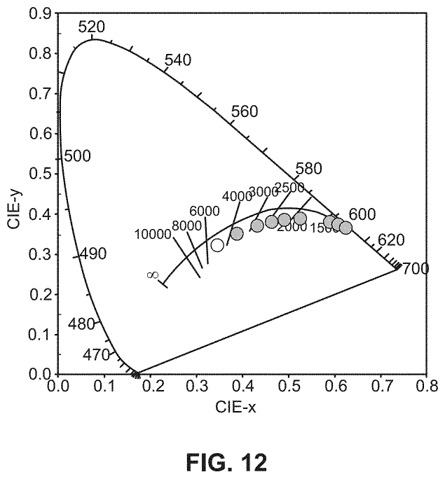

FIG. 12 shows a third CIE chromaticity diagram with measurement data obtained from OLED components. From the experimental data of FIG. 12, it is found that, the first lights emitted by the first lighting element 111 connected with multi stacked color temperature reducing films 112 have a color temperature rolling off with the adding of the number of the color temperature reducing films 112. Moreover, with the adding of the stacked numbers of the color temperature reducing films 112, the first lights radiated from different first lighting elements 111 are converted to a light resemblance with respect to sunlight in morning sessions, a light resemblance with respect to sunlight in early morning sessions or early evening sessions, an orange-white light, or an orange-red light. Herein, it needs to further explain that, when using OLED components with color temperature greater than 6,000 K, the second lighting element 113 is able to emit a light resemblance with respect to sunlight in noon sessions or a light resemblance with respect to blue sky sunlight.

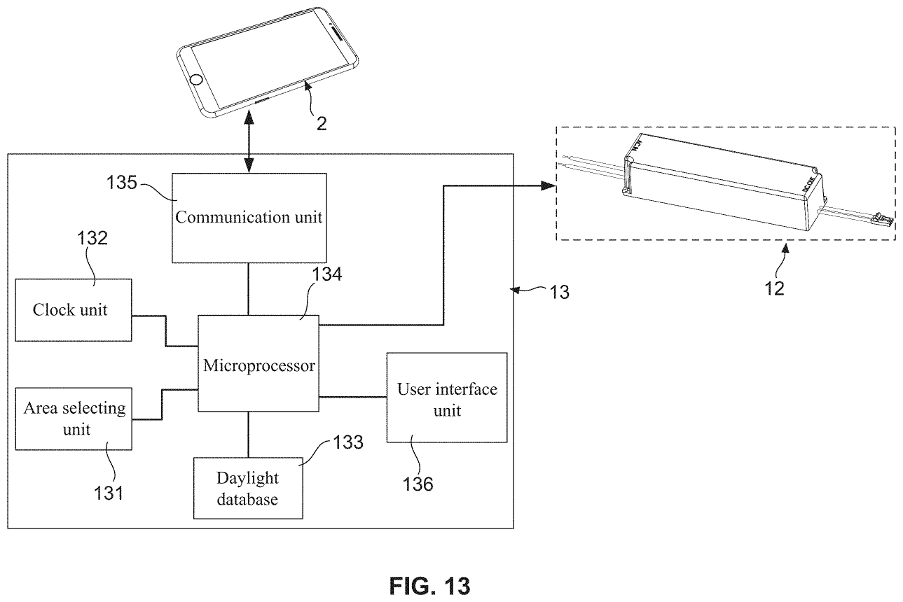

Referring to FIG. 4 and FIG. 5 again, and please simultaneously refer to FIG. 13, which shows a block diagram of the controller module. In the present invention, the controller module 13 comprises: a daylight database 133, an area selecting unit 131, a clock unit 132, and a microprocessor 134. The daylight database 133 stores with a plurality of daylight data corresponding to a plurality of areas, respectively, like Taiwan area of Asian or New York area of America USA. On the other hand, the daylight data comprises luminance data and color temperature data of a local daylight corresponding to the area. Moreover, the area selecting unit 131 is used for choosing a specific area from the daylight database, therefore the clock unit 132 would be configured to provide a local real time of the specific area chosen by the area selecting unit 131.

FIG. 13 also depicts that the microprocessor 134 is electrically connected to the area selecting unit 131, the clock unit 132 and the daylight database 133, and is configured to generate a controlling signal to the driver module 12 based on the daylight data and the local real time corresponding to the specific area chosen by the area selecting unit 131, such that the driver module 12 drives at least one of the plurality of first lighting elements 111 and/or the at least one second lighting element 113 to make light emission according to the controlling signal. As a result, the smart light source 1 of the present invention provides an illumination contributed by lights resemblance with respect to a local daylight (sunlight) in at least one session of local real time which is selected by an user through the controller module 13. In addition, the controller module 13 further comprises a communication unit 135 and a user interface unit 136. The communication unit 135 is electrically connected to the microprocessor 134 for facilitating the microprocessor 134 communicate with an electronic device 2, and the user interface unit is also electrically connected to the microprocessor 134 for facilitating an user to operate the controller module 13. In spite of the fact that FIG. 4 and FIG. 5 depicts that the electronic device 2 is a smart phone, that does not used for limit the practical type of the electronic device 2. Of course, the electronic device 2 can also be a desk computer, a laptop computer, a tablet PC, or a smart watch.

Second Embodiments of the Smart Light Source

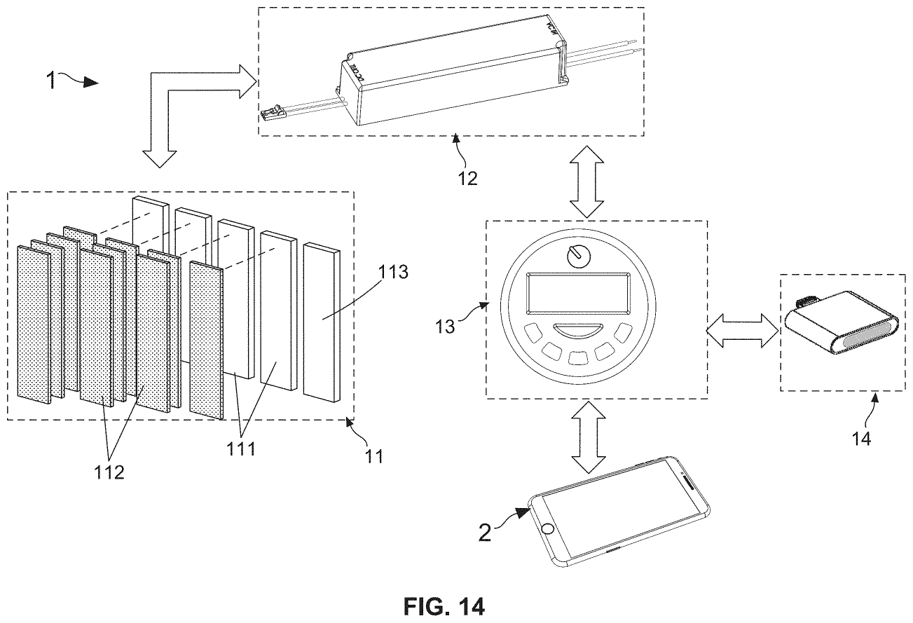

With reference to FIG. 14, there is provided a stereo diagram of a second embodiment of the smart light source according to the present invention. After comparing FIG. 14 with FIG. 5, it is found that the second embodiment of the smart light source 1 further comprises an optical receiver module 14. In the case of the fact that the illumination module 11, a driver module 12 and a controller module 13 of the smart light source 1 are disposed in an environment unable to receive a normal illumination provided by daylight (sunlight), such as spaceship, spacecraft, space capsule, mine, underground space, and small apartments or houses cannot have an enough sunlight illumination, the optical receiver module 14 can be disposed on the ground. By such arrangement, the optical receiver module 14 is able to receive a local daylight so as transmit a local daylight data comprising luminance data and color temperature data of the local daylight to the controller module 13. Therefore, the microprocessor 134 is configured to generates a controlling signal to the driver module 12 based on the daylight data and the local real time, such that the driver module 12 drives at least one of the plurality of first lighting elements 111 and/or the at least one second lighting element 113 to make light emission according to the controlling signal. As a result, the smart light source 1 of the present invention provides an illumination contributed by lights resemblance with respect to the local daylight (sunlight) in at least one session of local real time.

Therefore, through above descriptions, the smart light source 1 proposed by the present invention has been introduced completely and clearly; in summary, the present invention includes the advantages of:

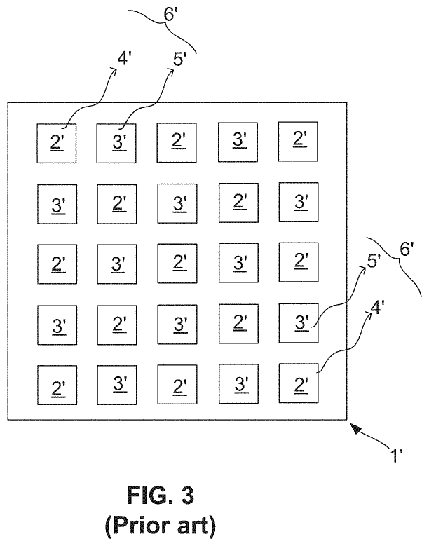

(1) Although conventional color temperature tunable (CCT) illuminous device 1′ (as shown in FIG. 3) has been developed for users to decide and adjust the brightness and color temperature of the light emitted from the CTT illuminous device 1′ by themselves, the CTT illuminous device 1′ is still unable to provide an illumination contributed by lights resemblance with respect to sunlight (daylight) because the maximum adjustment range of the color temperature of the CCT illuminous device 1′ relies upon color temperature adjustable capabilities of the lighting element array constituted by a plurality of first light emitting devices (LEDs) 2′ and a plurality of second LEDs 3′. Differing from the lighting technology applied in the conventional CTT illuminous device 1′, the present invention develops and provides a smart light source 1 comprising an illumination module 11, a driver module 12, and a controller module 13, wherein the illumination module 11 is particularly designed to have a plurality of first lighting elements 111, at least one second lighting element 113, and a plurality of color temperature reducing films 112. In the present invention, one or more color temperature reducing films 112 are disposed on a light emission surface of each of the plurality of first lighting elements 111. By such arrangement, first lights radiated from different first lighting elements 111 would be converted to a light resemblance with respect to sunlight in morning sessions, a light resemblance with respect to sunlight in early morning sessions or early evening sessions, an orange-white light, or an orange-red light by the CT reducing films. Moreover, the second lighting element 113 is configured to emit a high CT light, i.e., a light resemblance with respect to sunlight in noon sessions or a light resemblance with respect to blue sky sunlight.

Moreover, by operating the controller module 13, users are able to select a specific area like Taiwan area of Asian or New York area of America USA, so as to make the microprocessor 134 be configured to generates a controlling signal to the driver module 12 based on the daylight data and the local real time. Therefore, the driver module 12 drives at least one of the plurality of first lighting elements 111 and/or the at least one second lighting element 113 to make light emission according to the controlling signal. As a result, the smart light source 1 of the present invention provides an illumination to an environment unable to receive enough sunlight illumination, wherein the illumination is contributed by lights resemblance with respect to the local daylight (sunlight) in at least one session of local real time.

The above description is made on embodiments of the present invention. However, the embodiments are not intended to limit scope of the present invention, and all equivalent implementations or alterations within the spirit of the present invention still fall within the scope of the present invention.

1. A smart light source, comprising:
an illumination module, comprising:
a plurality of first lighting elements, wherein each of the plurality of first lighting elements is configured to emit a first multi-wavelength light, and the first multi-wavelength light is a pure-white light having a first color temperature that is equal to or higher than 6,000 k;
at least one second lighting element, being configured for emitting a second multi-wavelength light having a second color temperature that is close to a color temperature of a noon sunlight or approaches a color temperature of a blue sky sunlight; and
a plurality of color temperature reducing units, being respectively connected to the plurality of first lighting elements, and divided to a first group and a second group; wherein the respective color temperature reducing units in the first group comprise one color temperature reducing film, and the respective color temperature reducing units in the second group comprising two or more color temperature reducing films stacked to each other; wherein the respective color temperature reducing units are configured for applying a color temperature reducing process to the respective first lights, so as to make a decrease of the first color temperature of the first multi-wavelength light be proportional to a stack number of the color temperature reducing films;
a driver module, being electrically connected to the illumination module; and
a controller module, being used for controlling the driver module, and comprising:
a daylight database, storing with a plurality of daylight data corresponding to a plurality of areas, respectively;
an area selecting unit for choosing a specific area from the daylight database;
a clock unit for providing a local real time of the specific area chosen by the area selecting unit; and
a microprocessor, being electrically connected to the area selecting unit, the clock unit and the daylight database, and being configured to generate a controlling signal to the driver module based on the daylight data and the local real time corresponding to the specific area chosen by the area selecting unit, such that the driver module drives at least one of the plurality of first lighting elements and/or the at least one second lighting element to make light emission according to the controlling signal.

2. The smart light source of claim 1, being applied in an environment unable to receive a normal illumination provided by daylight.

3. The smart light source of claim 1, wherein the controller module further comprises:
a communication unit, being electrically connected to the microprocessor for facilitating the microprocessor communicate with an electronic device; and
a user interface unit, being electrically connected to the microprocessor.

4. The smart light source of claim 1, further comprising:
an optical receiver module, being electrically connected to the controller module, and being configured for receiving a local daylight so as transmit a local daylight data to the controller module.

5. The smart light source of claim 1, wherein both the plurality of first lighting elements and the at least one second lighting element are selected from the group consisting of fluorescent lighting device, LED component, QD-LED component, OLED component, fluorescent lighting device, LED lighting device, QD-LED lighting device, OLED lighting device, lighting tube, planar lighting device, and light bulb.

6. The smart light source of claim 1, wherein the first light is eventually converted to an orange-white light or an orange-red light, such that the first color temperature of the first light is reduced so as to be in a range between 1,000K and 2,500K.

7. The smart light source of claim 1, wherein the color temperature reducing film is a light conversion film comprising a polymer substrate and a plurality of light conversion particles, wherein the light conversion particles are doped in or enclosed by the polymer substrate.

8. The smart light source of claim 1, wherein the color temperature reducing film is a light conversion film comprising a polymer substrate and at least one light conversion coating layer formed on the polymer substrate.

9. The smart light source of claim 3, wherein the electronic device is selected from the group consisting of desk computer, laptop computer, tablet PC, smart phone, and smart watch.

10. The smart light source of claim 7, wherein the manufacturing material of the polymer substrate is selected from the group consisting of polydimethylsiloxane (PDMS), polystyrene (PS), polyethylene terephthalate (PET), polycarbonate (PC), cycloolefin co-polymer (COC), cyclic block copolymer (CBC), polylactide (PLA), polyimide (PI), and combination of the above-mentioned two or above materials.

11. The smart light source of claim 7, wherein the light conversion particles are quantum dots, and the quantum dot is selected from the group consisting of Group II-VI compounds, Group III-V compounds, Group II-VI compounds having core-shell structure, Group III-V compounds having core-shell structure, Group II-VI compounds having non-spherical alloy structure, and combination of the aforesaid two or above compounds.

12. The smart light source of claim 7, wherein the light conversion particles are particles of a phosphor, and the phosphor is selected from the group consisting of aluminate phosphor, silicate phosphor, phosphate phosphor, sulfide phosphor, and nitride phosphor.

13. The smart light source of claim 7, wherein an oxygen and moisture barrier is further disposed on the light conversion film, and the oxygen and moisture barrier is made of a specific material selected from the group consisting of polyethylene terephthalate (PET), polyethylene naphthalate (PEN), poly(methyl methacrylate) (PMMA), silica, titanium oxide, aluminum oxide, and combination of the aforesaid two or above materials.
